(19) United States
(12) Patent Application Publication
(10) Pub. No.: US 2026/0247706 A1
(43) Pub. Date: Aug. 20, 2026

(54) DISPLAY SUBSTRATE AND DISPLAY DEVICE

(71) Applicants: CHENGDU BOE OPTOELECTRONICS TECHNOLOGY CO., LTD., Sichuan (CN); BOE TECHNOLOGY GROUP CO., LTD., Beijing (CN)

(72) Inventors: Jiaxing Chen, Beijing (CN); Biao Liu, Beijing (CN); Haigang Qing, Beijing (CN); Lili Du, Beijing (CN); Yi An, Beijing (CN); Zhengkun Li, Beijing (CN); Tinghua Shang, Beijing (CN); Zuoji Niu, Beijing (CN)

(73) Assignees: CHENGDU BOE OPTOELECTRONICS TECHNOLOGY CO., LTD., Sichuan (CN); BOE TECHNOLOGY GROUP CO., LTD., Beijing (CN)

(21) Appl. No.: 18/869,961

(22) PCT Filed: Sep. 22, 2023
(86) PCT No.: PCT/CN2023/120687

§ 371 Date: Nov. 27, 2024

(51) Int. Cl. H10D 86/40; H10D 86/60; H10H 29/39

(52) U.S. Cl. CPC H10D 86/411; H10D 86/441; H10D 86/60; H10H 29/39

(57) ABSTRACT

A display substrate and a display device are provided. In the display substrate, a gate electrode of a first reset transistor is coupled to a corresponding first reset signal line, a first electrode of the first reset transistor is coupled to a corresponding first initialization signal line, and a second electrode of the first reset transistor is coupled to a gate electrode of a driving transistor; a gate electrode of a compensation transistor is coupled to a corresponding first scanning line, a first electrode of the compensation transistor is coupled to a second electrode of the driving transistor, and a second electrode of the compensation transistor is coupled to the gate electrode of the driving transistor; the first reset transistor includes a first reset active layer, the compensation transistor includes a compensation active layer.

### TECHNICAL FIELD

The present disclosure relates to the field of display technology, and in particular, to a display substrate and a display device.

### BACKGROUND

Low Temperature Polycrystalline Oxide (LTPO) technology has advantages such as high charge mobility, a high pixel response speed, and low power consumption. The LTPO technology has been increasingly used in a display product. With a development of a mobile phone and a wearable device, there is a growing demand for a higher resolution in the display product. The higher the resolution of an LTPO display product, the smaller a layout space that a sub-pixel driving circuit can occupy.

### SUMMARY

An object of the present disclosure is to provide a display substrate and a display device.

To achieve the above object, the present disclosure provides the following technical solution.

In a first aspect, the present disclosure provides a display substrate, including: a base substrate, and a plurality of sub-pixels, a plurality of first reset signal lines, a plurality of first scanning lines and a plurality of first initialization signal lines, each of which is arranged on the base substrate; the sub-pixel includes a sub-pixel driving circuit, and the sub-pixel driving circuit includes a driving transistor, a first reset transistor and a compensation transistor;
a gate electrode of the first reset transistor is coupled to the corresponding first reset signal line, a first electrode of the first reset transistor is coupled to the corresponding first initialization signal line, and a second electrode of the first reset transistor is coupled to a gate electrode of the driving transistor; a gate electrode of the compensation transistor is coupled to the corresponding first scanning line, a first electrode of the compensation transistor is coupled to a second electrode of the driving transistor, and a second electrode of the compensation transistor is coupled to the gate electrode of the driving transistor;
the first reset transistor includes a first reset active layer, the compensation transistor includes a compensation active layer, at least part of the first reset active layer extends along a first direction, at least part of the compensation active layer extends along the first direction, and the first reset active layer and the compensation active layer are arranged along the first direction.

Optionally, the display substrate further includes a plurality of power lines, wherein at least part of the power line extends along the first direction;
an orthographic projection of the power line onto the base substrate overlaps at least partially with an orthographic projection of the first reset active layer onto the base substrate; and/or, an orthographic projection of the power line onto the base substrate overlaps at least partially with an orthographic projection of the compensation active layer onto the base substrate.

Optionally, the first reset active layer includes a first reset channel part, wherein an orthographic projection of the first reset channel part onto the base substrate overlaps with an orthographic projection of the gate electrode of the first reset transistor onto the base substrate; the compensation active layer includes a compensation channel part, wherein an orthographic projection of the compensation channel part onto the base substrate overlaps with an orthographic projection of the gate electrode of the compensation transistor onto the base substrate;
the orthographic projection of the power line onto the base substrate covers the orthographic projection of the first reset channel part onto the base substrate; and/or, the orthographic projection of the power line onto the base substrate covers the orthographic projection of the compensation channel part onto the base substrate.

Optionally, the gate electrode of the driving transistor is coupled to the second electrode of the first reset transistor and the second electrode of the compensation transistor through a first conductive connection part; the orthographic projection of the power line onto the base substrate overlaps at least partially with an orthographic projection of the first conductive connection part onto the base substrate.

Optionally, the orthographic projection of the power line onto the base substrate completely covers the orthographic projection of the first conductive connection part onto the base substrate.

Optionally, the display substrate further includes a plurality of second scanning lines and a plurality of data lines, wherein at least part of the data line extends along the first direction; the sub-pixel driving circuit further includes a data writing transistor, wherein a gate electrode of the data writing transistor is coupled to the corresponding second scanning line, a first electrode of the data writing transistor is coupled to the corresponding data line, and a second electrode of the data writing transistor is coupled to a first electrode of the driving transistor;
at least part of the orthographic projection of the first conductive connection part onto the base substrate is located between an orthographic projection of the compensation active layer onto the base substrate and an orthographic projection of the data line onto the base substrate.

Optionally, the second scanning line includes a plurality of first scanning parts and a plurality of second scanning parts, the first scanning parts and the second scanning parts are alternately arranged along a second direction, the second direction intersects with the first direction, and along the first direction, a width of the first scanning part is greater than a width of the second scanning part;
an orthographic projection of the first scanning part onto the base substrate overlaps at least partially with an orthographic projection of a first end of the first conductive connection part onto the base substrate, and the first end of the first conductive connection part is coupled to the second electrode of the first reset transistor and the second electrode of the compensation transistor.

Optionally, the display substrate further includes a light-shielding layer, and the driving transistor includes a driving active layer;
the light-shielding layer includes a plurality of light-shielding main parts, a plurality of first light-shielding connection parts, and a plurality of second light-shielding connection parts, wherein the light-shielding main parts adjacent to each other along the first direction are coupled to each other through the corresponding first light-shielding connection parts, and the light-shielding main parts adjacent to each other along a second direction are coupled to each other through the corresponding second light-shielding connection parts, and the second direction intersects with the first direction; an orthographic projection of the light-shielding main part onto the base substrate overlaps at least partially with an orthographic projection of the corresponding driving active layer onto the base substrate.

Optionally, the first light-shielding connection part includes a strip-shaped structure extending along the first direction.

Optionally, at least part of an orthographic projection of the first light-shielding connection part onto the base substrate is located between an orthographic projection of the compensation active layer onto the base substrate and an orthographic projection of the first conductive connection part onto the base substrate.

Optionally, an orthographic projection of the first light-shielding connection part onto the base substrate overlaps at least partially with an orthographic projection of the power line onto the base substrate.

Optionally, an orthographic projection of the first light-shielding connection part onto the base substrate overlaps with the orthographic projection of the power line onto the base substrate at a first overlapping area, and the first overlapping area is greater than or equal to 90% of an area of the first light-shielding connection part.

Optionally, the display substrate further includes a plurality of light-emitting control signal lines; the sub-pixel further includes a light-emitting element; the sub-pixel driving circuit further includes a light-emitting control transistor, a gate electrode of the light-emitting control transistor is coupled to the corresponding light-emitting control signal line, a first electrode of the light-emitting control transistor is coupled to the second electrode of the driving transistor, and a second electrode of the light-emitting control transistor is coupled to an anode of the light-emitting element through a second conductive connection part and a third conductive connection part sequentially in that order; the power line includes a groove, and at least part of the third conductive connection part is located within the groove.

Optionally, an orthographic projection of the second conductive connection part onto the base substrate overlaps at least partially with an orthographic projection of the light-emitting control signal line onto the base substrate; and/or an orthographic projection of the third conductive connection part onto the base substrate overlaps at least partially with the orthographic projection of the light-emitting control signal line onto the base substrate.

Optionally, the sub-pixel driving circuit further includes a power control transistor, a gate electrode of the power control transistor is coupled to the corresponding light-emitting control signal line, a first electrode of the power control transistor is coupled to the corresponding power line, and a second electrode of the power control transistor is coupled to a first electrode of the driving transistor;
the power control transistor includes a power control active layer, and at least part of an orthographic projection of a bottom of the groove onto the base substrate is located between an orthographic projection of the third conductive connection part onto the base substrate and an orthographic projection of the power control active layer onto the base substrate.

Optionally, the display substrate further includes a plurality of data lines, and the orthographic projection of the power control active layer onto the base substrate overlaps at least partially with an orthographic projection of the data line onto the base substrate.

Optionally, the display substrate further includes a plurality of second reset signal lines and a plurality of second initialization signal lines; the sub-pixel driving circuit further includes a second reset transistor, a gate electrode of the second reset transistor is coupled to the corresponding second reset signal line, a first electrode of the second reset transistor is coupled to the corresponding second initialization signal line, and a second electrode of the second reset transistor is coupled to the anode of the light-emitting element;
the light-emitting control transistor includes a light-emitting control active layer; the second reset transistor includes a second reset active layer, and the second reset active layer and the light-emitting control active layer are arranged along the first direction.

Optionally, the first scanning line includes a plurality of third scanning parts and a plurality of fourth scanning parts, the third scanning parts and the fourth scanning parts are alternately arranged along a second direction, the second direction intersects with the first direction, and along the first direction, a width of the third scanning part is greater than a width of the fourth scanning part;
an orthographic projection of the third scanning part onto the base substrate overlaps at least partially with the orthographic projection of the compensation active layer onto the base substrate; an orthographic projection of the fourth scanning part onto the base substrate overlaps at least partially with the orthographic projection of the first conductive connection part onto the base substrate.

Optionally, the display substrate further includes a plurality of power compensation lines arranged along the first direction, the power compensation line include a plurality of first compensation parts and a plurality of second compensation parts, the first compensation parts and the second compensation parts are alternately arranged along a second direction, at least part of the first compensation part extends along the first direction, at least part of the second compensation part extends along the second direction, and the first compensation part and the second compensation part adjacent to each other are coupled;
the second compensation part is coupled to the power line; at least part of an orthographic projection of the first compensation part onto the base substrate is located between an orthographic projection of the data line onto the base substrate and the orthographic projection of the first conductive connection part onto the base substrate.

Based on the technical solution of the display substrate described above, an second aspect of the present disclosure provides a display device, including the above display substrate

### BRIEF DESCRIPTION OF THE DRAWINGS

The accompanying drawings described here are provided to offer a further understanding of the present disclosure and constitute a part of the present disclosure. The schematic embodiments of the present disclosure and their descriptions are used to explain the present disclosure and do not constitute undue limitations on it. In the drawings:

FIG. 1 is a schematic diagram of the circuit structure of a sub-pixel driving circuit provided in an embodiment of the present disclosure;

FIG. 2 is a schematic cross-sectional diagram of parts of film layers of the display substrate provided in an embodiment of the present disclosure;

FIG. 3 is a layout schematic diagram of the light-shielding layer in a display substrate provided in an embodiment of the present disclosure;

FIG. 4 is a layout schematic diagram of a polysilicon active layer in a display substrate provided in an embodiment of the present disclosure;

FIG. 5 is a layout schematic diagram of a first gate metal layer in a display substrate provided in an embodiment of the present disclosure;

FIG. 6 is a layout schematic diagram of a second gate metal layer in a display substrate provided in an embodiment of the present disclosure;

FIG. 7 is a layout schematic diagram of an oxide active layer in a display substrate provided in an embodiment of the present disclosure;

FIG. 8 is a layout schematic diagram of a third gate metal layer in a display substrate provided in an embodiment of the present disclosure;

FIG. 9 is a layout schematic diagram of some via holes in an interlayer insulation layer of a display substrate provided in an embodiment of the present disclosure;

FIG. 10 is a layout schematic diagram of parts of via holes in an interlayer insulation layer of a display substrate provided in an embodiment of the present disclosure;

FIG. 11 is a layout schematic diagram of a first source-drain metal layer in a display substrate provided in an embodiment of the present disclosure;

FIG. 12 is a schematic diagram of via holes formed in a passivation layer in a display substrate provided in an embodiment of the present disclosure;

FIG. 13 is a schematic diagram of via holes formed in a first planar layer in a display substrate provided in an embodiment of the present disclosure;

FIG. 14 is a layout schematic diagram of a second source-drain metal layer in a display substrate provided in an embodiment of the present disclosure.

FIG. 15 is a layout schematic diagram of a polysilicon active layer and a first gate metal layer in a display substrate provided by the embodiment of the present disclosure;

FIG. 16 is a layout schematic diagram of adding a light-shielding layer on the basis of the scheme of FIG. 15;

FIG. 17 is a layout schematic diagram of adding a second gate metal layer on the basis of the scheme of FIG. 15;

FIG. 18 is a layout schematic diagram of an oxide active layer, a second gate metal layer and a third gate metal layer in a display substrate provided by the embodiment of the present disclosure;

FIG. 19 is a layout schematic diagram of adding a first source-drain metal layer on the basis of the scheme of FIG. 15;

FIG. 20 is a layout schematic diagram of adding an interlayer insulating layer and a first source-drain metal layer on the basis of the scheme of FIG. 18;

FIG. 21 is a layout schematic diagram of adding an oxide active layer and a third gate metal layer on the basis of the scheme of FIG. 17;

FIG. 22 is a layout schematic diagram of adding an interlayer insulating layer and a first source-drain metal layer on the basis of the scheme of FIG. 21;

FIG. 23 is a layout schematic diagram of adding a second source-drain metal layer on the basis of the scheme of FIG. 22;

FIG. 24 is a layout schematic diagram of a first source-drain metal layer and a second source-drain metal layer in a display substrate provided in an embodiment of the present disclosure;

FIG. 25 is a layout schematic diagram of a light-shielding layer and a second source-drain metal layer in a display substrate provided in an embodiment of the present disclosure;

FIG. 26 shows a just contact connection mode between a first source-drain metal layer and a polysilicon active layer in a display substrate provided in an embodiment of the present disclosure;

FIG. 27 shows a side contact connection mode between a first source-drain metal layer and a polysilicon active layer in a display substrate provided in an embodiment of the present disclosure.

### DETAILED DESCRIPTION

In order to further illustrate a display substrate and a display device provided by an embodiment of the present disclosure, a detailed description is given below in conjunction with the accompanying drawings.

When a size of a display product is fixed, the higher a resolution of the display product, the smaller a layout space that a sub-pixel driving circuit can occupy, and the greater the difficulty in laying out the sub-pixel driving circuit. Therefore, how to reduce a layout difficulty of the sub-pixel driving circuit within a limited layout space becomes an urgent technical problem to be solved.

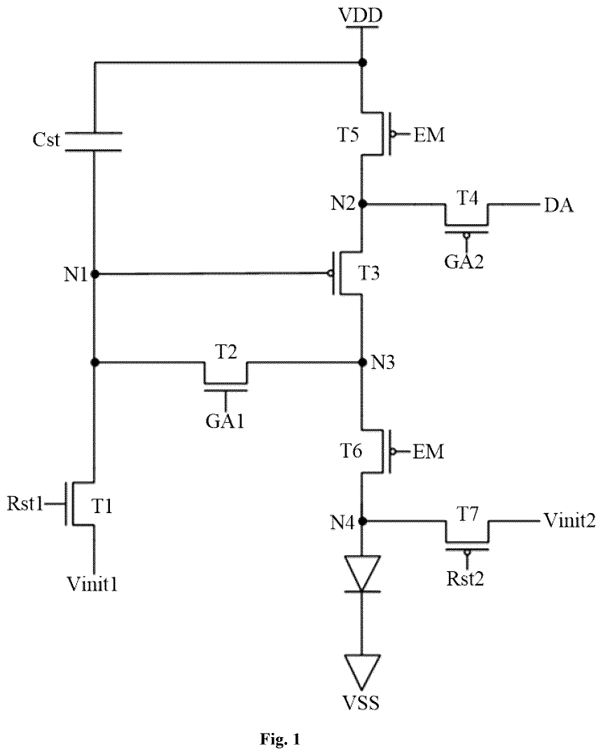

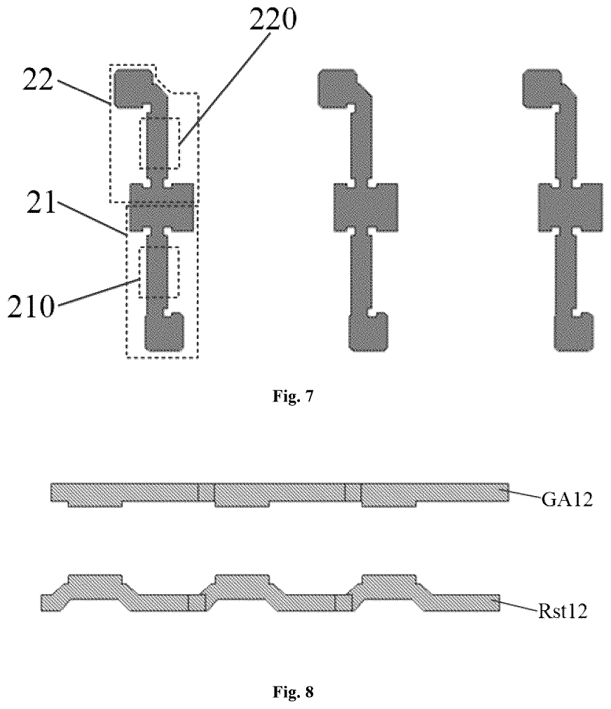

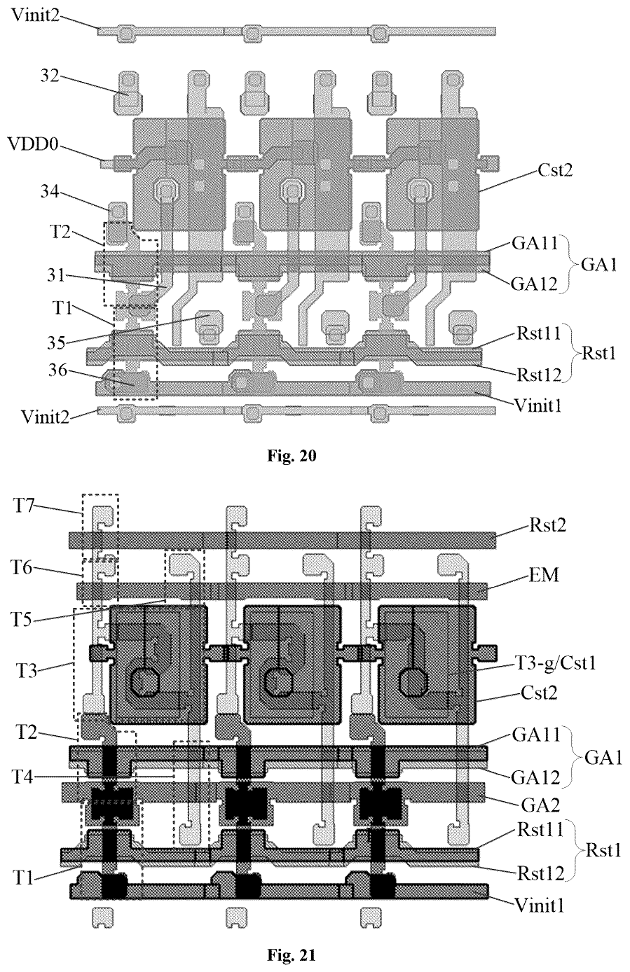

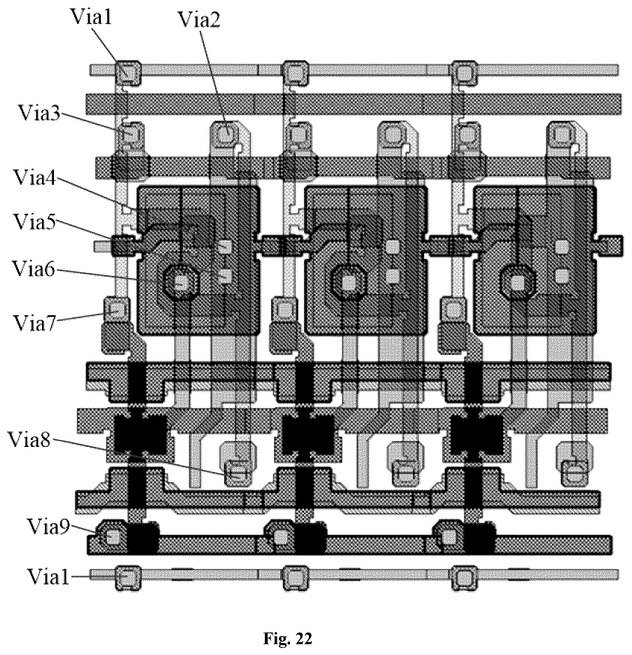

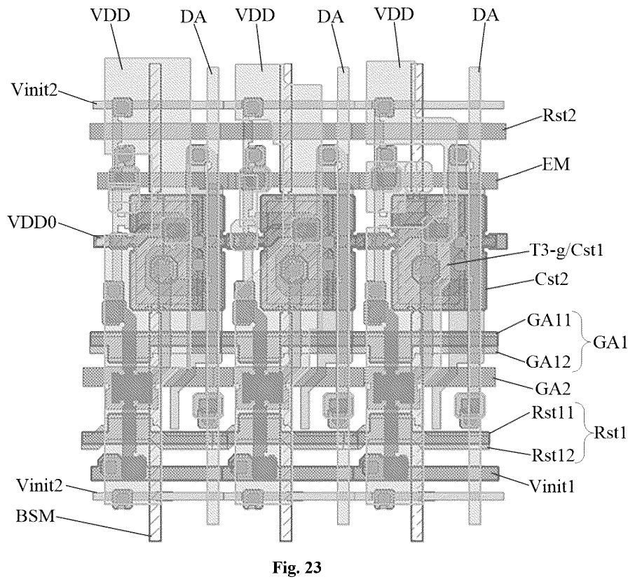

Please refer to FIGS. 1, 6 to 8, and 18 to 23. An embodiment of the present disclosure provides a display substrate, including: a base substrate and a plurality of sub-pixels all arranged on the base substrate, a plurality of first reset signal lines Rst1, a plurality of first scanning lines GA1, and a plurality of first initialization signal lines Vinit1; the sub-pixel includes a sub-pixel driving circuit, and the sub-pixel driving circuit includes a driving transistor T3, a first reset transistor T1, and a compensation transistor T2;
a gate electrode of the first reset transistor T1 is coupled to the corresponding first reset signal line Rst1, a first electrode of the first reset transistor T1 is coupled to the corresponding first initialization signal line Vinit1, and a second electrode of the first reset transistor T1 is coupled to a gate electrode T3-g of the driving transistor T3; a gate electrode of the compensation transistor T2 is coupled to the corresponding first scan line GA1, a first electrode of the compensation transistor T2 is coupled to a second electrode of the driving transistor T3, and a second electrode of the compensation transistor T2 is coupled to the gate electrode T3-g of the driving transistor T3;
the first reset transistor T1 includes a first reset active layer 21, the compensation transistor T2 includes a compensation active layer 22, at least part of the first reset active layer 21 extends along a first direction, at least part of the compensation active layer 22 extends along the first direction, and the first reset active layer 21 and the compensation active layer 22 are arranged along the first direction.

For example, the display substrate includes a plurality of sub-pixels, and the plurality of sub-pixel driving circuits included in the plurality of sub-pixels are arranged in an array. The plurality of sub-pixel driving circuits are divided into a plurality of rows of sub-pixel driving circuits and a plurality of columns of sub-pixel driving circuits. The plurality of rows of sub-pixel driving circuits are arranged along a first direction, and each row of sub-pixel driving circuits includes a plurality of sub-pixel driving circuits arranged along a second direction. The plurality of columns of sub-pixel driving circuits are arranged along a second direction, and each column of sub-pixel driving circuits includes a plurality of sub-pixel driving circuits arranged along the first direction. For example, the first direction and the second direction intersect. For example, the first direction includes a longitudinal direction, and the second direction includes a transverse direction.

For example, the sub-pixel includes a sub-pixel driving circuit and a light-emitting element. The sub-pixel driving circuit is coupled to an anode of the light-emitting element, and configured to provide a driving signal to the light-emitting element, to drive the light-emitting element to emit light.

For example, the plurality of first reset signal lines Rst1 are arranged along the first direction, and at least part of the first reset signal lines Rst1 extends along the second direction, and the first reset signal line Rst1 is configured to transmit a first reset signal. The plurality of first reset signal lines Rst1 correspond to the plurality of rows of sub-pixel driving circuits, respectively, and the first reset signal line Rst1 is coupled to each of the gate electrodes of first reset transistors T1 in the corresponding row of sub-pixel driving circuits. The first reset signal line Rst1 includes a first reset signal layer Rst11 and a second reset signal layer Rst12. The first reset signal layer Rst11 includes a fifth reset part 55 and a sixth reset part 56, and a width L5 of the fifth reset part 55 along the first direction is greater than a width L6 of the sixth reset part 56. An orthographic projection of the fifth reset part 55 onto the base substrate overlaps at least partially with an orthographic projection of the first reset active layer 21 onto the base substrate. The width of the second reset signal layer Rst12 may also be set according to a width of the first reset signal layer Rst11, which will not be elaborated here. The arrangement can ensure a channel width of the transistor, thereby guaranteeing the yield of the transistor characteristics.

For example, the plurality of first initialization signal lines Vinit1 are arranged along the first direction, at least part of the first initialization signal line Vinit1 extends along the second direction, and the first initialization signal line Vinit1 is configured to transmit the first initialization signal. The plurality of first initialization signal lines Vinit1 correspond to the plurality of rows of sub-pixel driving circuits, respectively, and the first initialization signal line Vinit1 is coupled to each of the first electrodes of first reset transistors T1 in the corresponding row of sub-pixel driving circuits.

For example, the plurality of first scanning lines GA1 are arranged along the first direction, at least part of the first scanning line GA1 extends along the second direction, and the first scanning line GA1 is configured to transmit a first scanning signal. The plurality of first scanning lines GA1 correspond to the plurality of rows of sub-pixel driving circuits, respectively, and the first scanning line GA1 is coupled to each of the gate electrodes of compensation transistors T2 in the corresponding row of sub-pixel driving circuits.

For example, each of the first reset transistor T1 and the compensation transistor T2 may include an oxide transistor, but the present disclosure is not limited thereto.

For example, the first reset active layer 21 and the compensation active layer 22 are made of Indium Gallium Zinc Oxide (IGZO) material, but the present disclosure is not limited thereto.

For example, the first reset active layer 21 includes a first reset main part, a first reset end, and a second reset end, the first reset main part is coupled to each of the first reset end and the second reset end, the first reset main part includes a first reset channel part 210, an orthographic projection of the first reset channel part 210 onto the base substrate overlaps with the orthographic projection of the gate electrode of the first reset transistor T1 onto the base substrate. The first reset main part extends along the first direction.

For example, the compensation active layer 22 includes a compensation main part, a first compensation end, and a second compensation end, the compensation main part is coupled to each of the first compensation end and the second compensation end, the compensation main part includes a compensation channel part 220, an orthographic projection of the compensation channel part 220 onto the base substrate overlaps with the orthographic projection of the gate electrode of the compensation transistor T2 onto the base substrate. The compensation main part extends along the first direction.

According to a specific structure of the display substrate described above, in the display substrate provided by the embodiment of the present disclosure, the first reset transistor T1 includes a first reset active layer 21, the compensation transistor T2 includes a compensation active layer 22, at least part of the first reset active layer 21 extends along the first direction, at least part of the compensation active layer 22 extends along the first direction, and the first reset active layer 21 and the compensation active layer 22 are arranged along the first direction. The above arrangement enables the first reset transistor T1 and the compensation transistor T2 to be arranged along the first direction, which is conducive to narrowing a width of the layout space occupied by the sub-pixel driving circuit in other directions intersecting with the first direction. At the same time, the above arrangement can further concentrate the various structures included in the sub-pixel driving circuit along the first direction, narrowing the width of the layout space occupied by the sub-pixel driving circuit along other directions.

Therefore, in the display substrate provided in the embodiment of the present disclosure, it is possible to narrow the layout space occupied by the sub-pixel driving circuit in other directions intersecting with the first direction, reduce the overall layout space occupied by the sub-pixel driving circuit, and reduce the difficulty of layout of the sub-pixel driving circuit within a limited layout space, so that the display substrate meets a development need of a high resolution.

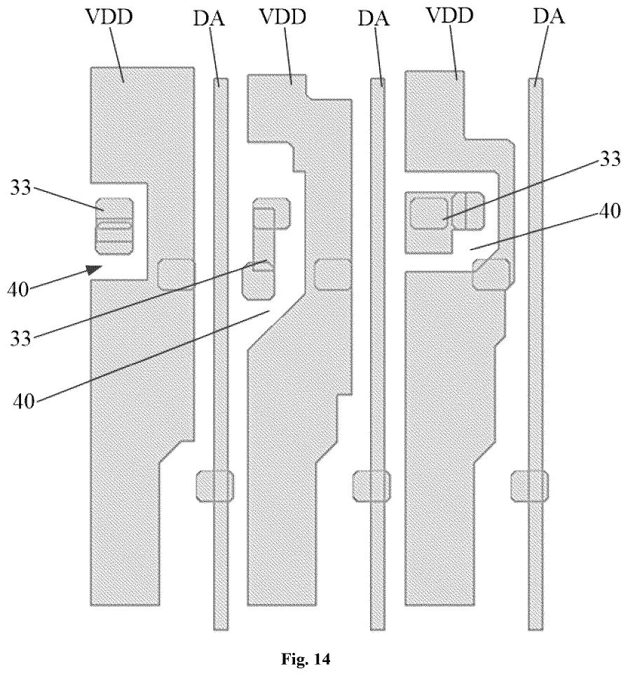

As shown in FIGS. 14, 18, and 20 to 23, in some embodiments, the display substrate further includes a plurality of power lines VDD, at least part of the power line VDD extends along the first direction; an orthographic projection of the power line VDD onto the base substrate overlaps at least partially with the orthographic projection of the first reset active layer 21 onto the base substrate; and/or, the orthographic projection of the power line VDD onto the base substrate overlaps at least partially with the orthographic projection of the compensation active layer 22 onto the base substrate.

For example, the plurality of power lines VDD are arranged along the second direction, at least part of the power lines VDD extends along the first direction, the plurality of power lines VDD correspond to the plurality of columns of sub-pixel driving circuits, respectively, and the power line VDD is coupled to each of the first electrodes of power control transistors T5 in the corresponding column of sub-pixel driving circuits. The power line VDD is configured to transmit a power signal.

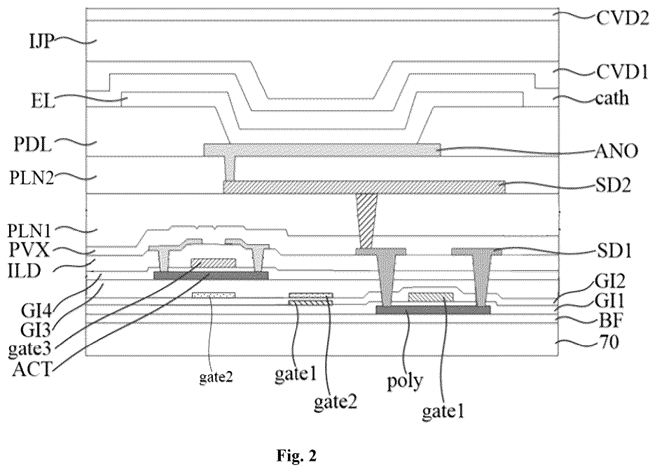

As shown in FIG. 2, for example, the display substrate includes a buffer layer BF, a light-shielding layer BSM, a polysilicon active layer poly, a first gate insulating layer GI1, a first gate metal layer gate1, a second gate insulating layer GI2, a second gate metal layer gate2, a third gate insulating layer GI3, an oxide active layer ACT, a fourth gate insulating layer GI4, a third gate metal layer gate3, an interlayer insulating layer ILD, a first source-drain metal layer SD1, a first planar layer PLN1, a second source-drain metal layer SD2, a second planar layer PLN2, an anode layer ANO, a pixel defining layer PDL, a light-emitting functional layer EL, a cathode layer cath, a first inorganic encapsulation layer CVD1, an organic encapsulation layer IJP, and a second inorganic encapsulation layer CVD2, which are sequentially stacked in a direction away from the base substrate 70. The display substrate may also be provided with a passivation layer PVX according to an actual need. The passivation layer PVX may be located between the first source-drain metal layer SD1 and the first planar layer PLN1, or may be located between the first planar layer PLN1 and the second source-drain metal layer SD2.

For example, the power line VDD is arranged in a same layer and made of a same material as the second source-drain metal layer, but the present disclosure is not limited thereto.

For example, the orthographic projection of the power line VDD onto the base substrate completely covers the orthographic projection of the first reset active layer 21 onto the base substrate; and/or, the orthographic projection of the power line VDD onto the base substrate completely covers the orthographic projection of the compensation active layer 22 onto the base substrate.

For example, an overlapping area between the orthographic projection of the power line VDD onto the base substrate and the orthographic projection of the first reset active layer 21 onto the base substrate is greater than or equal to 95% of an area of the first reset active layer 21; and/or, the overlapping area between the orthographic projection of the power line VDD onto the base substrate and the orthographic projection of the compensation active layer 22 onto the base substrate is greater than or equal to 95% of an area of the compensation active layer 22.

For example, the first reset active layer 21 includes a first reset channel part 210, an orthographic projection of the first reset channel part 210 onto the base substrate overlaps with the orthographic projection of the gate electrode of the first reset transistor T1 onto the base substrate; the compensation active layer 22 includes a compensation channel part 220, the orthographic projection of the compensation channel part 220 onto the base substrate overlaps with the orthographic projection of the gate electrode of the compensation transistor T2 onto the base substrate;
the orthographic projection of the power line VDD onto the base substrate covers the orthographic projection of the first reset channel part 210 onto the base substrate; and/or, the orthographic projection of the power line VDD onto the base substrate covers the orthographic projection of the compensation channel part 220 onto the base substrate.

It should be noted that, due to the characteristics of the IGZO, it is necessary to shield the active layer made of the IGZO with a metal film layer to prevent light from adversely affecting the characteristics of the transistor.

In the display substrate provided in the above embodiments, the orthographic projection of the power line VDD onto the base substrate overlaps at least partially with the orthographic projection of the first reset active layer 21 onto the base substrate; and/or the orthographic projection of the power line VDD onto the base substrate overlaps at least partially with the orthographic projection of the compensation active layer 22 onto the base substrate, which allows the power line VDD to block the light from irradiating the first reset active layer 21 and/or the compensation active layer 22, thereby ensuring the stability of the first reset transistor T1 and the compensation transistor T2.

In addition, since at least part of the first reset active layer 21 extends along the first direction, and at least part of the compensation active layer 22 extends along the first direction, the first reset active layer 21 and the compensation active layer 22 are arranged along the first direction; the width of the layout space occupied by the sub-pixel driving circuit in other directions intersecting with the first direction is narrowed. In this case, the power line VDD is utilized to shield the first reset active layer 21 and/or the compensation active layer 22, which allows to narrow the size of the power line VDD in the directions intersecting the first direction, reduce the layout space occupied by the power line VDD in the first direction, and improve the transmittance of the display substrate.

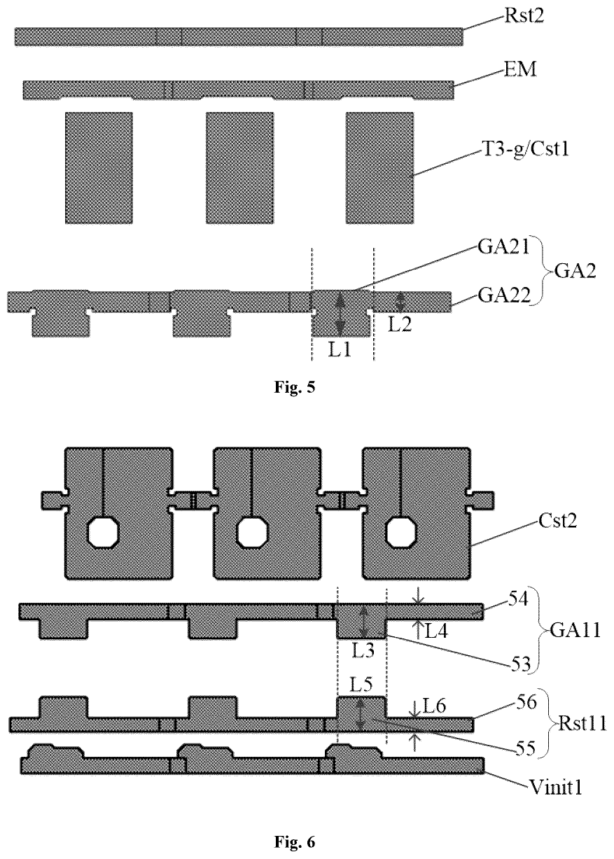

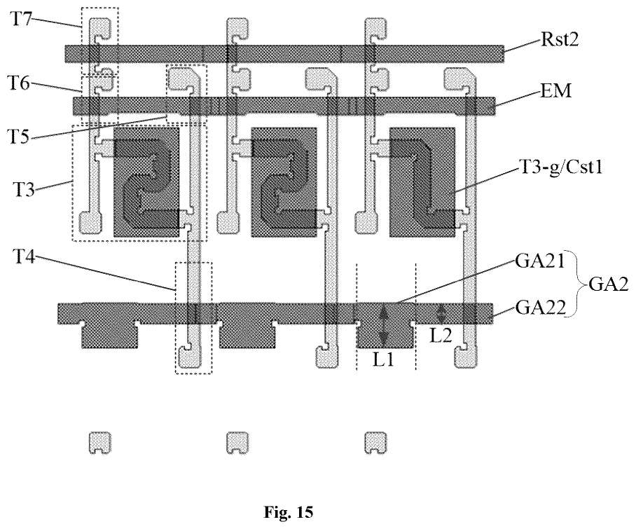

As shown in FIGS. 5, 11, 14, 15, 19, 22 and 23, in some embodiments, the gate electrode T3-g of the driving transistor T3 is coupled to the second electrode of the first reset transistor T1 and the second electrode of the compensation transistor T2 through the first conductive connection part 31; the orthographic projection of the power line VDD onto the base substrate overlaps at least partially with the orthographic projection of the first conductive connection part 31 onto the base substrate.

For example, the orthographic projection of the power line VDD onto the base substrate completely covers the orthographic projection of the first conductive connection part 31 onto the base substrate.

For example, the first conductive connection part 31 is arranged in a same layer and made of a same material as the first source-drain metal layer, but the present disclosure is not limited thereto.

It should be noted that the first conductive connection part 31 is formed as a node N1 in the sub-pixel driving circuit.

The above-mentioned arrangement of the orthographic projection of the power line VDD onto the base substrate overlaps at least partially with the orthographic projection of the first conductive connection part 31 onto the base substrate, so that the power line VDD can shield the first conductive connection part 31 while forming a parasitic capacitance relative to the first conductive connection part 31 to stabilize the voltage of the node N1.

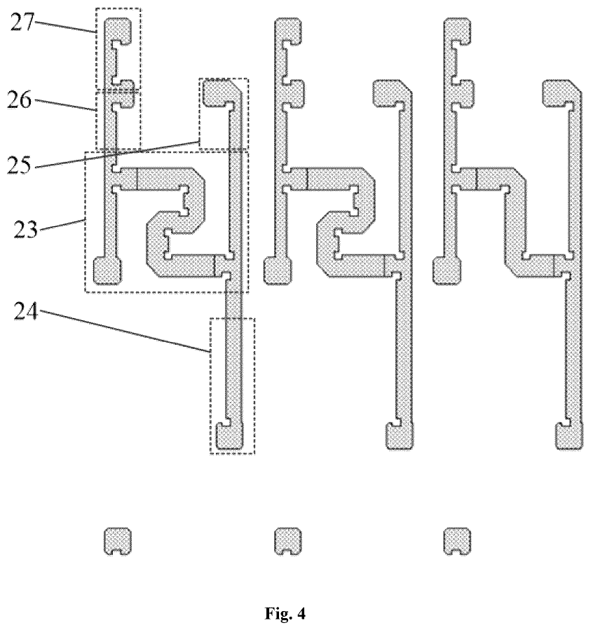

As shown in FIGS. 4, 5, 11, 14, 15, 19 and 23, in some embodiments, the display substrate further includes a plurality of second scanning lines GA2 and a plurality of data lines DA, and at least part of the data line DA extends along the first direction; the sub-pixel driving circuit further includes a data writing transistor T4, a gate electrode of the data writing transistor T4 is coupled to the corresponding second scanning line GA2, a first electrode of the data writing transistor T4 is coupled to the corresponding data line DA, and a second electrode of the data writing transistor T4 is coupled to the first electrode of the driving transistor T3;
at least part of the orthographic projection of the first conductive connection part 31 onto the base substrate is located between the orthographic projection of the compensation active layer 22 onto the base substrate and the orthographic projection of the data line DA onto the base substrate.

As shown in FIG. 4, for example, the data writing transistor T4 includes a data writing active layer 24.

For example, the plurality of second scanning lines GA2 are arranged along the first direction, at least part of the second scanning line GA2 extends along the second direction, and the second scanning line GA2 is configured to transmit a second scanning signal. The plurality of second scanning lines GA2 correspond to the plurality of rows of sub-pixel driving circuits, respectively, and the second scanning line GA2 is coupled to each of the gate electrodes of data writing transistors T4 in the corresponding row of sub-pixel driving circuits.

For example, the plurality of data lines DA are arranged along the second direction, at least part of the data line DA extends along the first direction, and the data line DA is configured to transmit a data signal. The plurality of data lines DA correspond to the plurality of columns of sub-pixel driving circuits, respectively, and the data line DA is coupled to each of the first electrodes of data writing transistors T4 in the corresponding column of sub-pixel driving circuits.

The above-mentioned arrangement enables an orderly layout of the first conductive connection part 31, the compensation active layer 22 and the data line DA, which can not only reduce the difficulty of connecting the first conductive connection part 31 with the second electrode of the first reset transistor T1 and the second electrode of the compensation transistor T2, but also help to narrow the layout space occupied by the sub-pixel driving circuit in the first direction.

As shown in FIGS. 5, 15, 21 and 22, in some embodiments, the second scanning line GA2 includes a plurality of first scanning parts GA21 and a plurality of second scanning parts GA22, the first scanning parts GA21 and the second scanning parts GA22 are alternately arranged along the second direction, the second direction intersects with the first direction, and along the first direction, the width L1 of the first scanning part GA21 is greater than the width L2 of the second scanning part GA22;
an orthographic projection of the first scanning part GA21 onto the base substrate overlaps at least partially with the orthographic projection of the first end of the first conductive connection part 31 onto the base substrate, and the first end of the first conductive connection part 31 is coupled to the second electrode of the first reset transistor T1 and the second electrode of the compensation transistor T2.

For example, the adjacent first scanning part GA21 and second scanning part GA22 form an integral structure, and the second scanning line GA2 is arranged in a same layer and made of a same material as the first gate metal layer.

For example, the orthographic projection of the first scanning part GA21 onto the base substrate overlaps at least partially with the orthographic projection of the first reset active layer 21 onto the base substrate, and the orthographic projection of the first scanning part GA21 onto the base substrate overlaps at least partially with the orthographic projection of the compensation active layer 22 onto the base substrate.

As shown in FIGS. 6 to 8, 11, 18 and 20, in some embodiments, the first scanning line GA1 includes a plurality of third scanning parts 53 and a plurality of fourth scanning parts 54, the third scanning parts 53 and the fourth scanning parts 54 are alternately arranged along the second direction, the second direction intersects with the first direction, and along the first direction, a width L3 of the third scanning part 53 is greater than a width L4 of the fourth scanning part 54;
an orthographic projection of the third scanning part 53 onto the base substrate overlaps at least partially with the orthographic projection of the compensation active layer 22 onto the base substrate; an orthographic projection of the fourth scanning part 54 onto the base substrate overlaps at least partially with the orthographic projection of the first conductive connection part 31 onto the base substrate.

For example, the first scanning line GA1 includes a first scanning layer GA11 and a second scanning layer GA12, the first scanning layer GA11 layer is arranged in a same layer and made of a same material as the second gate metal layer, and the second scanning layer GA12 is arranged in a same layer and made of a same material as the third gate metal layer. The first scanning layer GA11 includes a plurality of third scanning parts 53 and a plurality of fourth scanning parts 54. The second scanning layer GA12 includes a plurality of third scanning parts 53 and a plurality of fourth scanning parts 54. The third scanning parts 53 and the fourth scanning parts 54 that are in a same layer and adjacent to each other form an integrated structure.

For example, the orthographic projection of the third scanning part 53 onto the base substrate does not overlap with the orthographic projection of the first conductive connection part 31 onto the base substrate, and the orthographic projection of the fourth scanning part 54 onto the base substrate overlaps at least partially with the orthographic projection of the first conductive connection part 31 onto the base substrate.

In the above arrangement, the orthographic projection of the fourth scanning part 54 onto the base substrate overlap at least partially with the orthographic projection of the first conductive connection part 31 onto the base substrate; the orthographic projection of the first scanning part GA21 onto the base substrate overlaps at least partially with the orthographic projection of the first end of the first conductive connection part 31 onto the base substrate. Since the respective scanning signals transmitted by the first scanning line GA1 and the second scanning line GA2 have opposite effects on the potential of the first conductive connection part 31, the above arrangement can offset the effects of the respective scanning signals transmitted by the first scanning line GA1 and the second scanning line GA2 on the potential of the first conductive connection part 31, thereby ensuring the stability of the potential of the first conductive connection part 31.

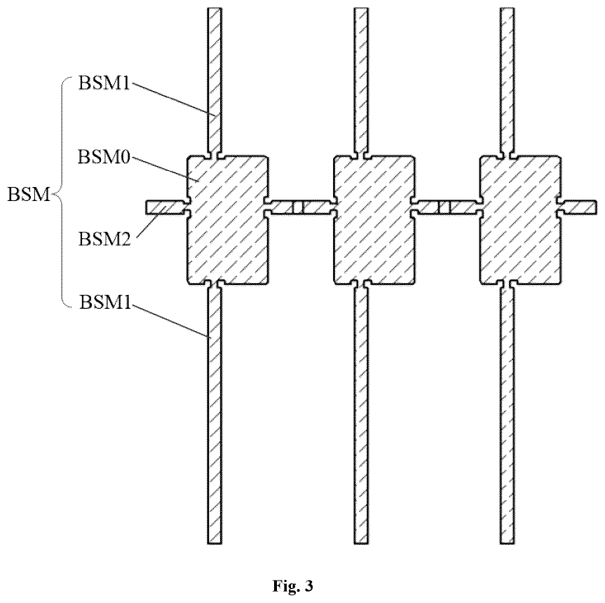

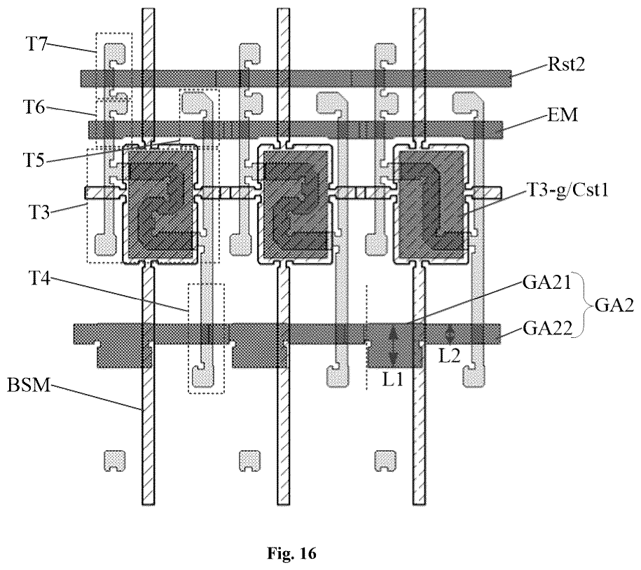

As shown in FIGS. 3, 4, 15 and 16, in some embodiments, the display substrate further includes a light-shielding layer BSM, and the driving transistor T3 includes a driving active layer 23; the light-shielding layer BSM includes a plurality of light-shielding main parts BSM0, a plurality of first light-shielding connection parts BSM1 and a plurality of second light-shielding connection parts BSM2, the light-shielding main parts BSM0 adjacent to each other along the first direction are coupled through the corresponding first light-shielding connection part BSM1, and the light-shielding main parts BSM0 adjacent to each other along the second direction are coupled through the corresponding second light-shielding connection part BSM2, and the second direction intersects with the first direction; an orthographic projection of the light-shielding main part BSM0 onto the base substrate overlaps at least partially with the orthographic projection of the corresponding driving active layer 23 onto the base substrate.

For example, the multiple light-shielding main parts BSM0 correspond to the multiple driving active layers 23 included in the multiple sub-pixel driving circuits in the multiple sub-pixels, respectively, and an orthographic projection of the light-shielding main part BSM0 onto the base substrate overlaps at least partially with the orthographic projection of the corresponding driving active layer 23 onto the base substrate. For example, the driving active layer 23 includes a driving channel part, and an orthographic projection of the driving channel part onto the base substrate overlaps with the orthographic projection of the gate electrode T3-g of the driving transistor T3 onto the base substrate, and the orthographic projection of the light-shielding main part BSM0 onto the base substrate completely covers the orthographic projection of the driving channel part in the corresponding driving active layer 23 onto the base substrate.

In the display substrate provided by the above embodiments, the orthographic projection of the light-shielding main part BSM0 onto the base substrate overlaps at least partially with the orthographic projection of the corresponding driving active layer 23 onto the base substrate, such that the light-shielding main part BSM0 can prevent the light from irradiating the driving active layer 23, thereby ensuring the characteristics of the driving transistor T3.

As shown in FIGS. 3, 4, 15 and 16, in some embodiments, the first light-shielding connection part BSM1 includes a strip-like structure extending along the first direction.

For example, at least part of an orthographic projection of the first light-shielding connection part BSM1 onto the base substrate is located between the orthographic projection of the compensation active layer 22 onto the base substrate and the orthographic projection of the first conductive connection part 31 onto the base substrate.

For example, at least part of the orthographic projection of the first light-shielding connection part BSM1 onto the base substrate is located between the orthographic projection of the first reset active layer 21 onto the base substrate and the orthographic projection of the data line DA onto the base substrate.

The above-mentioned arrangement enables the first light-shielding connection part BSM1 to avoid the channel part included in the transistor, that is, the orthographic projection of the first light-shielding connection part BSM1 onto the base substrate does not overlap with an orthographic projection of the channel part included in the transistor onto the base substrate, thereby preventing the first light-shielding connection part BSM1 from adversely affecting the operation of the transistor.

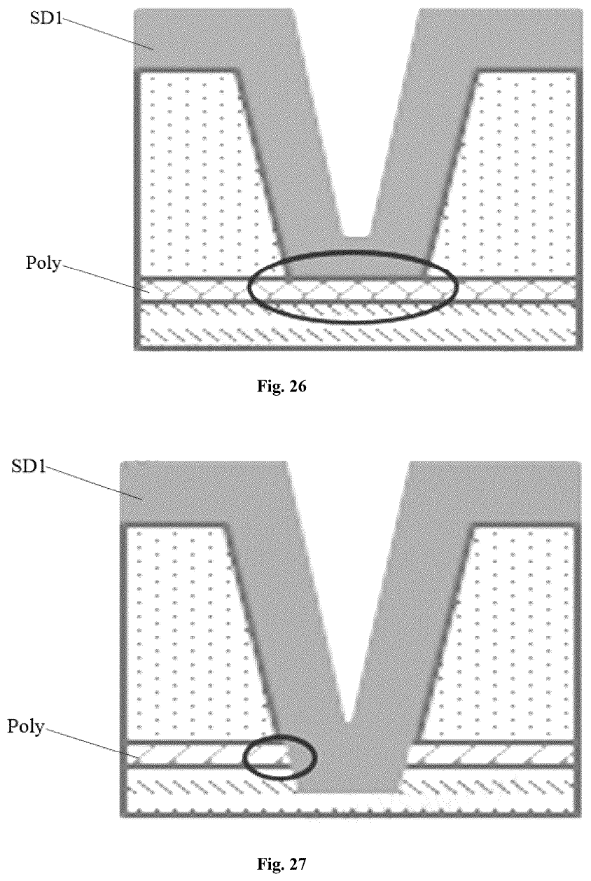

The above-mentioned arrangement enables the first light-shielding connection part BSM1 to avoid a via hole penetrating the interlayer insulating layer, thereby ensuring the manufacturing yield of the display substrate. More specifically, as shown in FIGS. 26 and 27, specific connection modes between the first source-drain metal layer SD1 and the polysilicon active layer poly through the via hole include side contact mode and just contact mode. The side contact mode has relatively better resistance and fluctuation (only ⅙ of the fluctuation), while the just contact mode requires surface management of the overlapping area on the upper part of the polysilicon active layer poly and ensures high-precision etching processes. Thus, the side contact mode is superior by comparison. When the side contact mode is adopted, it is necessary to penetrate the polysilicon active layer poly. If the light-shielding layer BSM is located below the penetrated polysilicon active layer poly and is close to the penetrated polysilicon active layer poly, there is a risk of short circuit between the first source-drain metal layer SD1 and the polysilicon active layer poly.

The display substrate adopts the above-mentioned arrangement, allowing the first light-shielding connection part BSM1 can extend vertically without bending. This arrangement can narrow the layout space occupied by the sub-pixel driving circuit in other directions intersecting with the first direction, reduce the overall layout space occupied by the sub-pixel driving circuit, and reduce the difficulty of layout of the sub-pixel driving circuit within a limited layout space, so that the display substrate meets a development need of a high resolution.

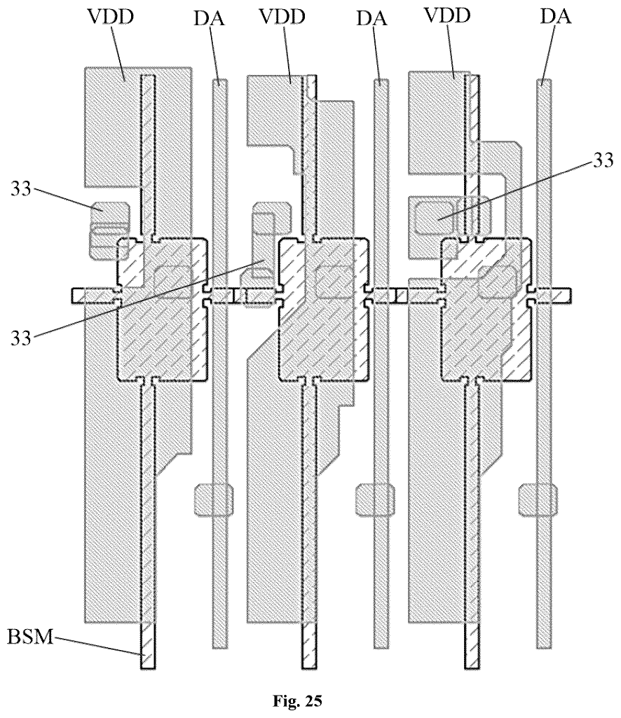

As shown in FIG. 25, in some embodiments, the orthographic projection of the first light-shielding connection part BSM1 onto the base substrate overlaps at least partially with the orthographic projection of the power line VDD onto the base substrate.

For example, the orthographic projection of the first light-shielding connection part BSM1 onto the base substrate overlaps with the orthographic projection of the power line VDD onto the base substrate at a first overlapping area, and the first overlapping area is greater than or equal to 90% of the area of the first light-shielding connection part BSM1.

For example, the orthographic projection of the first light-shielding connection part BSM1 onto the base substrate completely covers the orthographic projection of the power line VDD onto the base substrate.

In the display substrate provided in the above embodiment, the orthographic projection of the first light-shielding connection part BSM1 onto the base substrate overlaps at least partially with the orthographic projection of the power line VDD onto the base substrate, such that the first light-shielding connection part BSM1 can be shielded by the power line VDD, while improving the transmittance of the display substrate. In addition, it can reduce the layout space occupied by the first light-shielding connection part BSM1 in the horizontal direction. This design is highly beneficial for optimizing lateral space in high-resolution projects, especially real RGB projects.

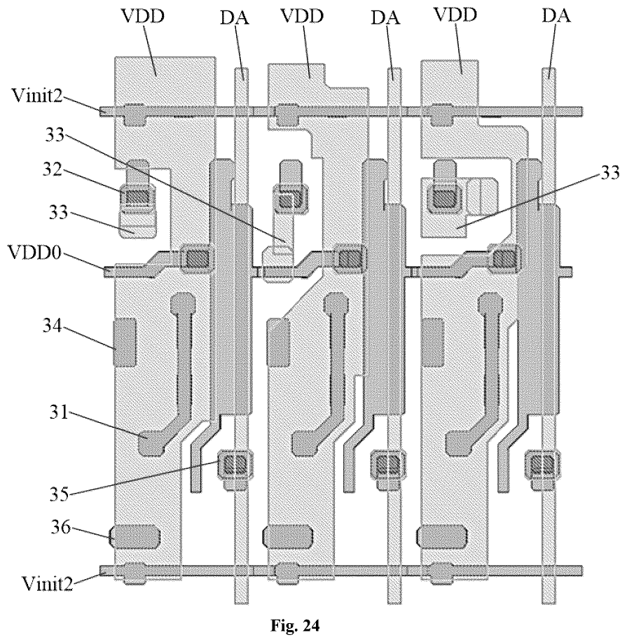

As shown in FIGS. 14, 21, 23, 24 and 25, in some embodiments, the display substrate further includes a plurality of light-emitting control signal lines EM; the sub-pixel further includes a light-emitting element; the sub-pixel driving circuit further includes a light-emitting control transistor T6, the gate electrode of the light-emitting control transistor T6 is coupled to the corresponding light-emitting control signal line EM, the first electrode of the light-emitting control transistor T6 is coupled to the second electrode of the driving transistor T3, and the second electrode of the light-emitting control transistor T6 is coupled to the anode of the light-emitting element through the second conductive connection part 32 and the third conductive connection part 33 sequentially in that order; the power line VDD includes a groove 40, and at least part of the third conductive connection part 33 is located within the groove 40.

For example, the plurality of light-emitting control signal lines EM are arranged along the first direction, and at least part of the light-emitting control signal line EM extends along the second direction. The plurality of light-emitting control signal lines EM correspond to the plurality of rows of sub-pixel driving circuits, respectively, and the light-emitting control signal line EM is coupled to each of the gate electrodes of power control transistors T5 in the corresponding row of sub-pixel driving circuits, and the gate electrodes of light-emitting control transistors T6. The light-emitting control signal line EM is configured to transmit a light-emitting control signal.

For example, the second conductive connection part 32 is arranged in a same layer and made of a same material as the first source-drain metal layer, the third conductive connection part 33 is arranged in a same layer and made of a same material as the second source-drain metal layer, and the power line VDD is arranged in a same layer and made of a same material as the second source-drain metal layer.

The power line VDD includes a groove 40, and at least part of the third conductive connection part 33 is located within the groove 40, so as to narrow the layout space occupied by the third conductive connection part 33 and the power line VDD in other directions intersecting with the first direction, reduce the layout difficulty of the sub-pixel driving circuit within a limited layout space, resulting in that the display substrate meets a development need of the high resolution.

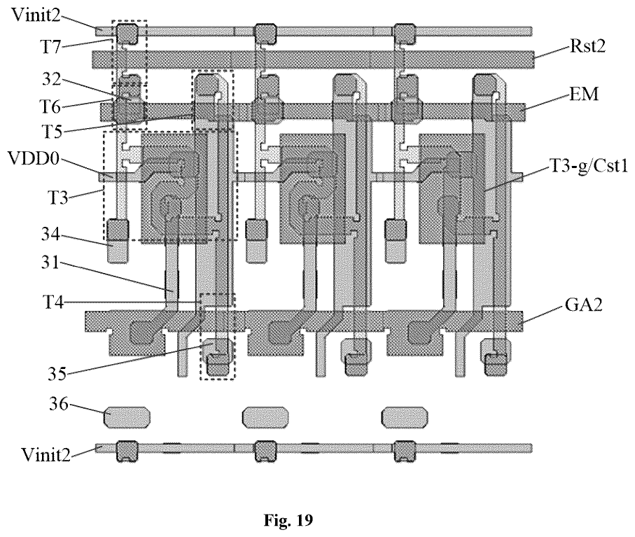

As shown in FIGS. 19, 20, 23 and 24, in some embodiments, the orthographic projection of the second conductive connection part 32 onto the base substrate overlaps at least partially with an orthographic projection of the light-emitting control signal line EM onto the base substrate; and/or, the orthographic projection of the third conductive connection part 33 onto the base substrate overlaps at least partially with the orthographic projection of the light-emitting control signal line EM onto the base substrate.

The above-mentioned arrangement is conducive to improving the transmittance of the display substrate.

As shown in FIGS. 14, 21, 23, 24 and 25, in some embodiments, the sub-pixel driving circuit further includes a power control transistor T5, the gate electrode of the power control transistor T5 is coupled to the corresponding light-emitting control signal line EM, the first electrode of the power control transistor T5 is coupled to the corresponding power line VDD, and the second electrode of the power control transistor T5 is coupled to the first electrode of the driving transistor T3; the power control transistor T5 includes a power control active layer 25, and at least part of an orthographic projection of a bottom of the groove 40 onto the base substrate is located between an orthographic projection of the third conductive connection part 33 onto the base substrate and an orthographic projection of the power control active layer 25 onto the base substrate.

The above-mentioned arrangement reasonably utilizes the layout space of the display substrate, so as to narrow the layout space occupied by the sub-pixel driving circuit in other directions intersecting with the first direction, reduce the overall layout space occupied by the sub-pixel driving circuit, and reduce the layout difficulty of the sub-pixel driving circuit within the limited layout space, resulting in that the display substrate meets a development need of a high resolution.

As shown in FIGS. 4, 15 and 23, in some embodiments, the display substrate further includes a plurality of data lines DA, and the orthographic projection of the power control active layer 25 onto the base substrate overlaps at least partially with the orthographic projection of the data line DA onto the base substrate.

The above-mentioned arrangement can narrow the layout space occupied by the sub-pixel driving circuit in other directions intersecting with the first direction, reduce the overall layout space occupied by the sub-pixel driving circuit, and reduce the layout difficulty of the sub-pixel driving circuit within the limited layout space, so that the display substrate meets a development need of a high resolution. Moreover, the above-mentioned arrangement is also conducive to improving the transmittance of the display substrate.

As shown in FIGS. 4, 15 and 19, in some embodiments, the display substrate further includes a plurality of second reset signal lines Rst2 and a plurality of second initialization signal lines Vinit2; the sub-pixel driving circuit further includes a second reset transistor T7, the gate electrode of the second reset transistor T7 is coupled to the corresponding second reset signal line Rst2, the first electrode of the second reset transistor T7 is coupled to the corresponding second initialization signal line Vinit2, and the second electrode of the second reset transistor T7 is coupled to the anode of the light-emitting element; the light-emitting control transistor T6 includes a light-emitting control active layer 26; the second reset transistor T7 includes a second reset active layer 27, and the second reset active layer 27 and the light-emitting control active layer 26 are arranged along the first direction.

For example, the plurality of second reset signal lines Rst2 are arranged along the first direction, and at least part of the second reset signal line Rst2 extends along the second direction. The plurality of second reset signal lines Rst2 correspond to the plurality of rows of sub-pixel driving circuits, respectively, and the second reset signal line Rst2 is coupled to each of the gate electrodes of the second reset transistors T7 in the corresponding row of sub-pixel driving circuits. The second reset signal line Rst2 is configured to transmit a second reset signal.

For example, the plurality of second initialization signal lines Vinit2 are arranged along the first direction, and at least part of the second initialization signal line Vinit2 extends along the second direction. The plurality of second initialization signal lines Vinit2 correspond to the plurality of rows of sub-pixel driving circuits, respectively, and the second initialization signal line Vinit2 is coupled to each of the first electrodes of second reset transistors T7 in the corresponding row of sub-pixel driving circuits. The second initialization signal line Vinit2 is configured to transmit a second initialization signal.

For example, the second initialization signal line Vinit2 is arranged in a same layer and made of a same material as the first source-drain metal layer.

In the above-mentioned arrangement, the second reset active layer 27 and the light-emitting control active layer 26 are arranged along the first direction, so as to narrow the layout space occupied by the sub-pixel driving circuit in other directions intersecting with the first direction, reduce the overall layout space occupied by the sub-pixel driving circuit, and reduce the layout difficulty of the sub-pixel driving circuit within the limited layout space, resulting in that the display substrate meets a development need of a high resolution.

The specific structure of the sub-pixel driving circuit may be varied.

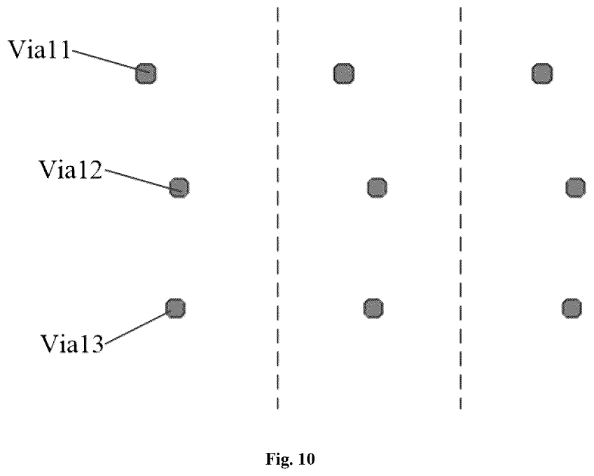

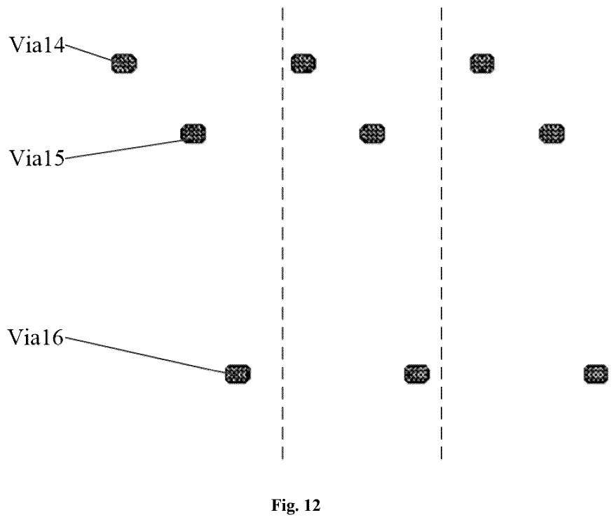

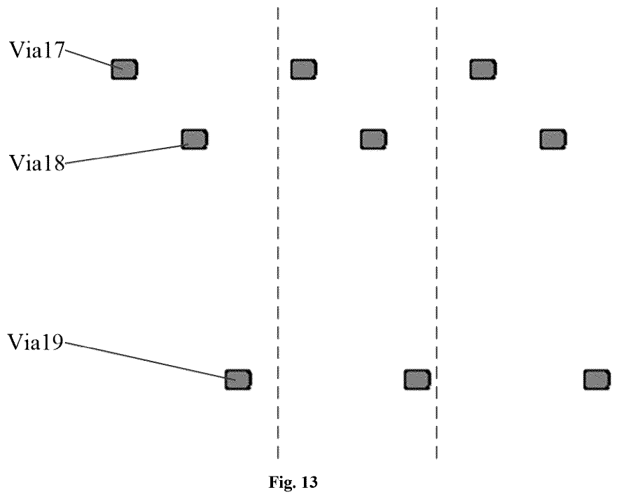

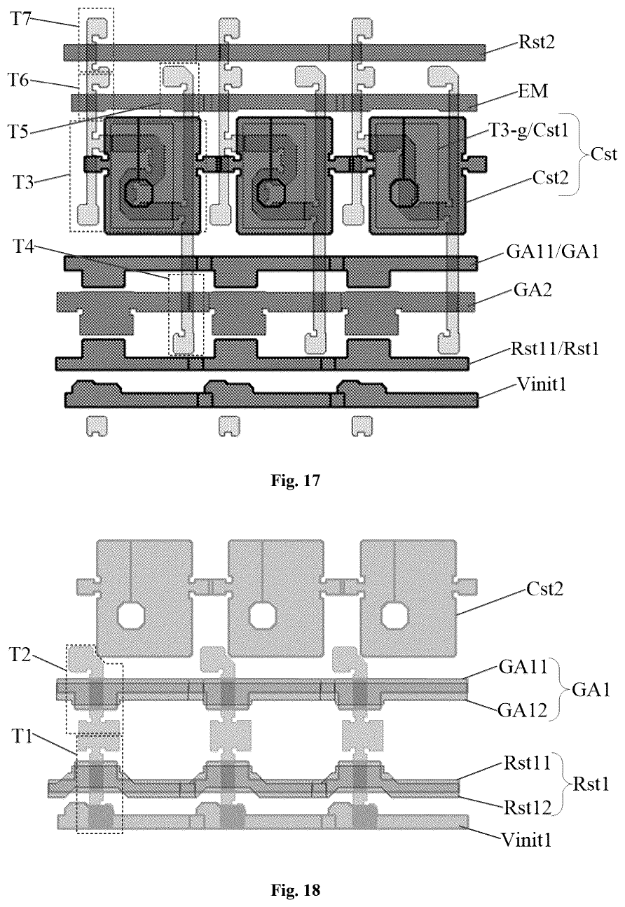

As shown in FIGS. 1 to 25, in some embodiments, the display substrate includes a first reset signal line Rst1, a second reset signal line Rst2, a light-emitting control signal line EM, a first scanning line GA1, a second scanning line GA2, a first initialization signal line, a second initialization signal line Vinit2, a power line VDD and a data line DA. The sub-pixel driving circuit includes a driving transistor T3, a compensation transistor T2, a data writing transistor T4, a first reset transistor T1, a second reset transistor T7, a power control transistor T5, a light-emitting control transistor T6 and a storage capacitor Cst.

The gate electrode of the first reset transistor T1 is coupled to the corresponding first reset signal line Rst1, the first electrode of the first reset transistor T1 is coupled to the first initialization signal line, and the second electrode of the first reset transistor T1 is coupled to the gate electrode T3-g (i.e., the first node N1) of the driving transistor T3.

The gate electrode of the compensation transistor T2 is coupled to the corresponding first scanning line GA1, the first electrode of the compensation transistor T2 is coupled to the second electrode of the driving transistor T3 (i.e., the third node N3), and the second electrode of the compensation transistor T2 is coupled to the gate electrode T3-g of the driving transistor T3.

The gate electrode of the data writing transistor T4 is coupled to the corresponding second scanning line GA2, the first electrode of the data writing transistor T4 is coupled to the corresponding data line DA, and the second electrode of the data writing transistor T4 is coupled to the first electrode of the driving transistor T3 (i.e., the second node N2).

The gate electrode of the power control transistor T5 is coupled to the corresponding light-emitting control signal line EM, the first electrode of the power control transistor T5 is coupled to the corresponding power line VDD, and the second electrode of the power control transistor T5 is coupled to the first electrode of the driving transistor T3.

The gate electrode of the light-emitting control transistor T6 is coupled to the corresponding light-emitting control signal line EM, the first electrode of the light-emitting control transistor T6 is coupled to the second electrode of the driving transistor T3, and the second electrode of the light-emitting control transistor T6 is coupled to the anode of the corresponding light-emitting element (i.e., the N4 node). The cathode of the light-emitting element receives a negative power signal VSS.

A first plate Cst1 of the storage capacitor Cst is coupled to the gate electrode T3-g of the driving transistor T3, and a second plate Cst2 of the storage capacitor Cst is coupled to the corresponding power line VDD.

For example, each of the first reset transistor T1 and the compensation transistor T2 includes an oxide transistor. Each of the driving transistor T3, the data writing transistor T4, the power control transistor T5, the light-emitting control transistor T6 and the second reset transistor T7 includes a low-temperature polysilicon transistor.

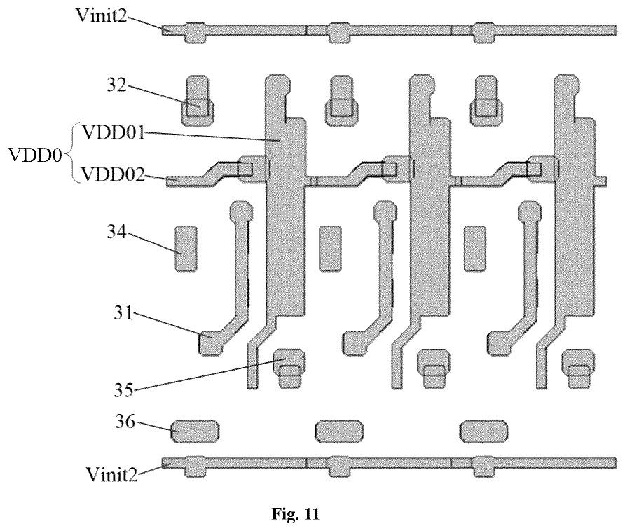

As shown in FIGS. 11, 23 and 24, in some embodiments, the display substrate further includes a plurality of power compensation lines VDD0 arranged along the first direction, the power compensation line VDD0 includes a plurality of first compensation parts VDD01 and a plurality of second compensation parts VDD02, the first compensation parts VDD01 and the second compensation parts VDD02 are alternately arranged along the second direction, at least part of the first compensation part VDD01 extends along the first direction, at least part of the second compensation part VDD02 extends along the second direction, and the first compensation parts VDD01 and second compensation parts VDD02 adjacent to each other are coupled;

the second compensation part VDD02 is coupled to the power line VDD; at least part of an orthographic projection of the first compensation part VDD01 onto the base substrate is located between the orthographic projection of the data line DA onto the base substrate and the orthographic projection of the first conductive connection part 31 onto the base substrate.

For example, the first compensation part VDD01 and the second compensation part VDD02 form an integral structure. The power compensation line VDD0 is arranged in a same layer and made of a same material as the first source-drain metal layer.

For example, the second compensation part VDD02 is coupled to each of the second plate Cst2 of the storage capacitor Cst and the first electrode of the power control transistor T5.

The display substrate may further include a power compensation line VDD0, so as to form a grid-like structure between the power compensation line VDD0 and the power line VDD, thereby effectively reducing the overall load of a film layer configured to transmit the power signal and improving the uniformity of the power signal.

At least part of the orthographic projection of the first compensation part VDD01 onto the base substrate is located between the orthographic projection of the data line DA onto the base substrate and the orthographic projection of the first conductive connection part 31 onto the base substrate, which allows the first compensation part VDD01 to effectively shield the interference from the data signal transmitted by the data line DA on the signal of the first conductive connection part 31, thereby ensuring the stability of the node N1.

The power compensation line VDD0 may further include the first compensation part VDD01, so as to allow the first compensation part VDD01 to effectively compensate for the planarity of the anode in the display substrate.

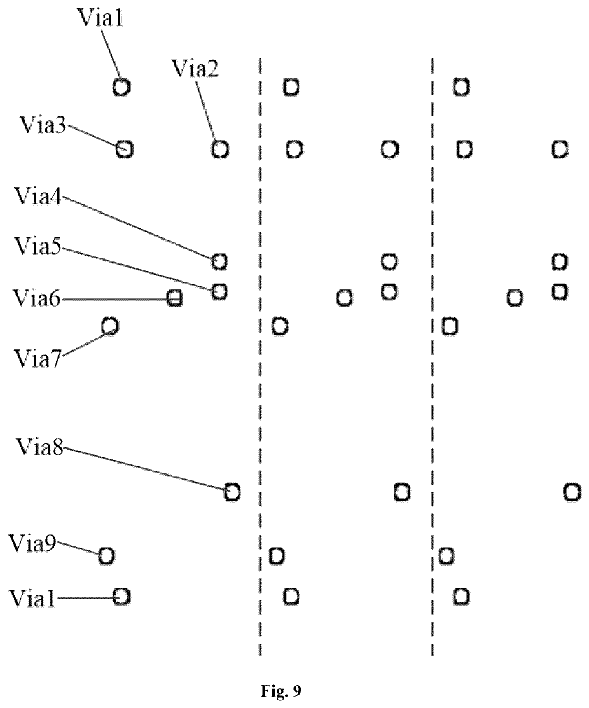

As shown in FIGS. 9, 10, 11, 12, 13, 15, 19 and 22, the first electrode of the second reset transistor T7 is coupled to the second initialization signal line Vinit2 through first via hole Via1.

The first electrode of the power control transistor T5 is coupled to the first compensation part VDD01 through a second via hole Via2. The second compensation part VDD02 is coupled to the power line VDD through a fifteenth via hole Via15 and a eighteenth via hole Via18.

The second electrode of the second reset transistor T7 and the second electrode of the light-emitting control transistor T6 are coupled to the second conductive connection part 32 through a third via hole Via3. The second conductive connection part 32 is coupled to the third conductive connection part 33 through a fourteenth via hole Via14 and a seventeenth via hole Via17.

The second plate Cst2 of the storage capacitor Cst is coupled to the first compensation part VDD01 through a fourth via hole Via4 and a fifth via hole Via5.

The first conductive connection part 31 is coupled to the gate electrode T3-g of the driving transistor T3 through a sixth via hole Via6. The first conductive connection part 31 is coupled to the second electrode of the first reset transistor T1 and the second electrode of the compensation transistor T2 through a twelfth via hole Via12.

The first electrode of the compensation transistor T2 is coupled to the fourth conductive connection part 34 through a eleventh via hole Via11. The fourth conductive connection part 34 is coupled to the second electrode of the driving transistor T3 through a seventh via hole Via7.

The first electrode of the data writing transistor T4 is coupled to the fifth conductive connection part 35 through an eighth via hole Via8. The fifth conductive connection part 35 is coupled to the data line DA through a sixteenth via hole Via16 and a nineteenth via hole Via19.

The sixth conductive connection part 36 is coupled to the first initialization signal line Vinit1 through a ninth via hole Via9, and the sixth conductive connection part 36 is coupled to the first electrode of the first reset transistor T1 through a thirteenth via hole Via13.

The embodiments of the present disclosure also provides a display device, including the display substrate provided by the above embodiments.

It should be noted that the display device can be any product or component with a display function, such as a television, a monitor, a digital photo frame, a mobile phone, a tablet computer, etc., wherein the display device may also include a flexible circuit board, a printed circuit board, and a backplane, etc.

In the display substrate provided by the above embodiment, the first reset transistor includes a first reset active layer, the compensation transistor includes a compensation active layer, at least part of the first reset active layer extends along the first direction, at least part of the compensation active layer extends along the first direction, and the first reset active layer and the compensation active layer are arranged along the first direction. In the above arrangement, it enables the first reset transistor and the compensation transistor to be arranged along the first direction, which is conducive to narrowing the width of the layout space occupied by the sub-pixel driving circuit in other directions intersecting with the first direction. At the same time, the above arrangement can further concentrate the various structures included in the sub-pixel driving circuit along the first direction, narrowing the width of the layout space occupied by the sub-pixel driving circuit along other directions. Therefore, in the display substrate provided by the above embodiments, the layout space occupied by the sub-pixel driving circuit in other directions intersecting with the first direction can be narrowed, the overall layout space occupied by the sub-pixel driving circuit can be reduced, and the layout difficulty of the sub-pixel driving circuit within the limited layout space can be reduced, so that the display substrate meets the development need of a high resolution.

Therefore, the display device provided by the embodiments of the present disclosure also has the above-mentioned beneficial effects when including the above-mentioned display substrate, which will not be repeated herein.

It should be noted that the signal line extends along the X direction means that: the signal line includes a main part and a secondary part connected to the main part, the main part is a line, a line segment or a strip-shaped body, the main part extends along the X direction, and a length of the main part extending along the X direction is greater than a length of the secondary part extending along other directions.

It should be noted that the layout area occupied by each sub-pixel driving circuit may be an area that accommodates the sub-pixel driving circuit. For example, the area may be selected as a rectangular area, but the present disclosure is not limited to this.

It should be noted that the “same layer” in the embodiments of the present disclosure may refer to a film layer on a same structural layer. Alternatively, for example, the film layer in the same layer may be a film layer for forming a specific pattern formed by a same deposition process, and then the film layer is patterned by the same mask through one patterning process to form a layer structure. Depending on the specific pattern, the one patterning process may include multiple exposures, developments or etching processes, and the specific pattern in the formed layer structure may be continuous or discontinuous. The specific patterns may also be at different heights or have different thicknesses.

In the method embodiments of the present disclosure, the serial numbers of the steps cannot be used to limit the order of the steps. Those of ordinary skill in the art may change the order of the steps without creative efforts, which falls within the scope of the present disclosure.

It should be noted that embodiments in this specification are described in a progressive manner, and the same or similar parts between the embodiments can be referred to each other, and each embodiment highlights differences from other embodiments. In particular, for a method embodiment, since it is basically similar to a product embodiment, it is described relatively briefly, with relevant parts referring to the partial description of the product embodiment.

Unless otherwise defined, the technical terms or scientific terms used in the present disclosure should be the common meanings understood by those of ordinary skill in the art. Terms like “first,” “second,” and similar words used in the present disclosure do not indicate any order, quantity or importance, but are only used to distinguish different components. “Include” or “comprise” and similar words indicate that the elements or objects appearing before the word include the elements or objects listed after the word and their equivalents, without excluding other elements or objects. “Connect”, “couple” or “connected” and similar words are not limited to physical or mechanical connections, but may include electrical connections, whether direct or indirect. Terms like “top”, “bottom”, “left”, “right”, etc. are only used to indicate relative position relationships. When the absolute position of the described object changes, the relative position relationship may also change accordingly.

It is understood that when an element such as a layer, film, region or substrate is referred to as being “on” or “under” another element, the element may be “directly” “on” or “under” another element, or there may be an intermediate element therebetween.

The above are only detailed description of the present disclosure, but the protection scope of the present disclosure is not limited thereto. Any variations or substitutions that may be readily conceived by those skilled in the art within the technical scope disclosed in the present disclosure should be included in the protection scope of the present disclosure. Therefore, the protection scope of the present disclosure should be based on the protection scope of the claims.

1. A display substrate, comprising: a base substrate, and a plurality of sub-pixels, a plurality of first reset signal lines, a plurality of first scanning lines and a plurality of first initialization signal lines, each of which is arranged on the base substrate; the sub-pixel comprises a sub-pixel driving circuit, and the sub-pixel driving circuit comprises a driving transistor, a first reset transistor and a compensation transistor;
a gate electrode of the first reset transistor is coupled to the corresponding first reset signal line, a first electrode of the first reset transistor is coupled to the corresponding first initialization signal line, and a second electrode of the first reset transistor is coupled to a gate electrode of the driving transistor; a gate electrode of the compensation transistor is coupled to the corresponding first scanning line, a first electrode of the compensation transistor is coupled to a second electrode of the driving transistor, and a second electrode of the compensation transistor is coupled to the gate electrode of the driving transistor;
the first reset transistor comprises a first reset active layer, the compensation transistor comprises a compensation active layer, at least part of the first reset active layer extends along a first direction, at least part of the compensation active layer extends along the first direction, and the first reset active layer and the compensation active layer are arranged along the first direction.

2. The display substrate according to claim 1, further comprising a plurality of power lines, wherein at least part of the power line extends along the first direction;
an orthographic projection of the power line onto the base substrate overlaps at least partially with an orthographic projection of the first reset active layer onto the base substrate; and/or, an orthographic projection of the power line onto the base substrate overlaps at least partially with an orthographic projection of the compensation active layer onto the base substrate.

3. The display substrate according to claim 2, wherein the first reset active layer comprises a first reset channel part, wherein an orthographic projection of the first reset channel part onto the base substrate overlaps with an orthographic projection of the gate electrode of the first reset transistor onto the base substrate; the compensation active layer comprises a compensation channel part, wherein an orthographic projection of the compensation channel part onto the base substrate overlaps with an orthographic projection of the gate electrode of the compensation transistor onto the base substrate;
the orthographic projection of the power line onto the base substrate covers the orthographic projection of the first reset channel part onto the base substrate; and/or, the orthographic projection of the power line onto the base substrate covers the orthographic projection of the compensation channel part onto the base substrate.

4. The display substrate according to claim 2, wherein the gate electrode of the driving transistor is coupled to the second electrode of the first reset transistor and the second electrode of the compensation transistor through a first conductive connection part; the orthographic projection of the power line onto the base substrate overlaps at least partially with an orthographic projection of the first conductive connection part onto the base substrate.

5. The display substrate according to claim 4, wherein the orthographic projection of the power line onto the base substrate completely covers the orthographic projection of the first conductive connection part onto the base substrate.

6. The display substrate according to claim 4, further comprising a plurality of second scanning lines and a plurality of data lines, wherein at least part of the data line extends along the first direction; the sub-pixel driving circuit further comprises a data writing transistor, wherein a gate electrode of the data writing transistor is coupled to the corresponding second scanning line, a first electrode of the data writing transistor is coupled to the corresponding data line, and a second electrode of the data writing transistor is coupled to a first electrode of the driving transistor;
at least part of the orthographic projection of the first conductive connection part onto the base substrate is located between an orthographic projection of the compensation active layer onto the base substrate and an orthographic projection of the data line onto the base substrate.

7. The display substrate according to claim 6, wherein the second scanning line comprises a plurality of first scanning parts and a plurality of second scanning parts, the first scanning parts and the second scanning parts are alternately arranged along a second direction, the second direction intersects with the first direction, and along the first direction, a width of the first scanning part is greater than a width of the second scanning part;
an orthographic projection of the first scanning part onto the base substrate overlaps at least partially with an orthographic projection of a first end of the first conductive connection part onto the base substrate, and the first end of the first conductive connection part is coupled to the second electrode of the first reset transistor and the second electrode of the compensation transistor.

8. The display substrate according to claim 4, further comprising a light-shielding layer, and the driving transistor comprises a driving active layer;
the light-shielding layer comprises a plurality of light-shielding main parts, a plurality of first light-shielding connection parts, and a plurality of second light-shielding connection parts, wherein the light-shielding main parts adjacent to each other along the first direction are coupled to each other through the corresponding first light-shielding connection parts, and the light-shielding main parts adjacent to each other along a second direction are coupled to each other through the corresponding second light-shielding connection parts, and the second direction intersects with the first direction; an orthographic projection of the light-shielding main part onto the base substrate overlaps at least partially with an orthographic projection of the corresponding driving active layer onto the base substrate.

9. The display substrate according to claim 8, wherein the first light-shielding connection part comprises a strip-shaped structure extending along the first direction.

10. The display substrate according to claim 9, wherein at least part of an orthographic projection of the first light-shielding connection part onto the base substrate is located between an orthographic projection of the compensation active layer onto the base substrate and an orthographic projection of the first conductive connection part onto the base substrate.

11. The display substrate according to claim 9, wherein an orthographic projection of the first light-shielding connection part onto the base substrate overlaps at least partially with an orthographic projection of the power line onto the base substrate.

12. The display substrate according to claim 11, wherein an orthographic projection of the first light-shielding connection part onto the base substrate overlaps with the orthographic projection of the power line onto the base substrate at a first overlapping area, and the first overlapping area is greater than or equal to 90% of an area of the first light-shielding connection part.

13. The display substrate according to claim 2, further comprising a plurality of light-emitting control signal lines; the sub-pixel further comprises a light-emitting element; the sub-pixel driving circuit further comprises a light-emitting control transistor, a gate electrode of the light-emitting control transistor is coupled to the corresponding light-emitting control signal line, a first electrode of the light-emitting control transistor is coupled to the second electrode of the driving transistor, and a second electrode of the light-emitting control transistor is coupled to an anode of the light-emitting element through a second conductive connection part and a third conductive connection part sequentially in that order; the power line comprises a groove, and at least part of the third conductive connection part is located within the groove.

14. The display substrate according to claim 13, wherein an orthographic projection of the second conductive connection part onto the base substrate overlaps at least partially with an orthographic projection of the light-emitting control signal line onto the base substrate; and/or an orthographic projection of the third conductive connection part onto the base substrate overlaps at least partially with the orthographic projection of the light-emitting control signal line onto the base substrate.

15. The display substrate according to claim 13, wherein the sub-pixel driving circuit further comprises a power control transistor, a gate electrode of the power control transistor is coupled to the corresponding light-emitting control signal line, a first electrode of the power control transistor is coupled to the corresponding power line, and a second electrode of the power control transistor is coupled to a first electrode of the driving transistor;
the power control transistor comprises a power control active layer, and at least part of an orthographic projection of a bottom of the groove onto the base substrate is located between an orthographic projection of the third conductive connection part onto the base substrate and an orthographic projection of the power control active layer onto the base substrate.

16. The display substrate according to claim 15, further comprising a plurality of data lines, and the orthographic projection of the power control active layer onto the base substrate overlaps at least partially with an orthographic projection of the data line onto the base substrate.

17. The display substrate according to claim 13, further comprising a plurality of second reset signal lines and a plurality of second initialization signal lines; the sub-pixel driving circuit further comprises a second reset transistor, a gate electrode of the second reset transistor is coupled to the corresponding second reset signal line, a first electrode of the second reset transistor is coupled to the corresponding second initialization signal line, and a second electrode of the second reset transistor is coupled to the anode of the light-emitting element;
the light-emitting control transistor comprises a light-emitting control active layer; the second reset transistor comprises a second reset active layer, and the second reset active layer and the light-emitting control active layer are arranged along the first direction.

18. The display substrate according to claim 4, wherein the first scanning line comprises a plurality of third scanning parts and a plurality of fourth scanning parts, the third scanning parts and the fourth scanning parts are alternately arranged along a second direction, the second direction intersects with the first direction, and along the first direction, a width of the third scanning part is greater than a width of the fourth scanning part;
an orthographic projection of the third scanning part onto the base substrate overlaps at least partially with the orthographic projection of the compensation active layer onto the base substrate; an orthographic projection of the fourth scanning part onto the base substrate overlaps at least partially with the orthographic projection of the first conductive connection part onto the base substrate.

19. The display substrate according to claim 4, further comprising a plurality of power compensation lines arranged along the first direction, the power compensation line comprise a plurality of first compensation parts and a plurality of second compensation parts, the first compensation parts and the second compensation parts are alternately arranged along a second direction, at least part of the first compensation part extends along the first direction, at least part of the second compensation part extends along the second direction, and the first compensation part and the second compensation part adjacent to each other are coupled;
the first compensation part is coupled to the power line; at least part of an orthographic projection of the second compensation part onto the base substrate is located between an orthographic projection of the data line onto the base substrate and the orthographic projection of the first conductive connection part onto the base substrate.

20. A display device comprising a display substrate according to claim 1.
